(19) United States
(12) Patent Application Publication
(10) Pub. No.: US 2008/0303098 A1
(43) Pub. Date: Dec. 11, 2008

(54) Semiconductor Device Manufactured Using a Method to Reduce CMP Damage to Low-K Dielectric Material

(75) Inventors: Yaojian Leng, Plano, TX (US); Robert D. Slater, Murphy, TX (US); Nathan J. Kruse, McKinney, TX (US)

Correspondence Address: TEXAS INSTRUMENTS INCORPORATED, P O BOX 655474, M/S 3999, DALLAS, TX, 75265, US

(73) Assignee: Texas Instruments, Incorporated, Dallas, TX (US)

(21) Appl. No.: 11/759,288

(22) Filed: Jun. 7, 2007

(51) Int. Cl. H01L 29/76; H01L 21/302

(52) U.S. Cl. 257/368; 438/692; 257/E29.346; 257/E21.219

(57) ABSTRACT

In one aspect, there is provided a method of manufacturing a semiconductor device. The method comprises depositing a barrier layer over a low-k dielectric layer located over a semiconductor substrate over which a metal layer is deposited. A chemical mechanical polish process is used to remove a portion of the metal layer and the barrier layer and a dry etch is used to remove a remaining portion of the barrier layer.

### TECHNICAL FIELD

The invention is directed, in general, to a semiconductor device and method of manufacture thereof and, more particularly, to a semiconductor device and manufacturing method to reduce damage to a low-k dielectric material from the effects of chemical mechanical polishing.

### BACKGROUND

Semiconductor device geometries have dramatically decreased in size since such devices were first introduced several decades ago. As components have scaled and transistors have gotten closer together, so, too, have the interconnect structures to connect the smaller components in the semiconductor device. The insulating dielectric in interconnect structures have thinned to the point where charge build-up and crosstalk adversely affect the performance of the device. To address these problems, manufacturers have begun replacing silicon dioxide dielectric material with low-k dielectric material of the same thickness to reduce parasitic capacitance, thus enabling faster switching speeds and lower heat dissipation.

However, one drawback of the use of low-k dielectric materials is that they are porous. When exposed to water, a low-k dielectric material can degrade (such as increasing its dielectric constant). Most of the degradation is non-recoverable, even after baking the material. Increasing the dielectric constant of the low-k dielectric material increases parasitic capacitance in the interconnect structure, defeating the purpose of using the low-k dielectric material in the first place. Also, exposing porous, low-k dielectric material to water/moisture increases the occurrence of subsequent cracking of the low-k dielectric material, leading to reliability issues with the finished semiconductor device. Additionally, low-k dielectric material is prone to mechanical damage such as scratches during subsequent processing such a chemical mechanical processing (CMP). Low-k dielectric material is harder to clean and dry due to its porousness and hydrophobicity.

CMP is often used in semiconductor processing to planarize the topography of an interconnect layer prior to depositing a subsequent interconnect layer. Typically a water-based slurry is used during the CMP process and the semiconductor wafer is rinsed with high pressure water after the polishing step. The semiconductor wafer is then cleaned with water based chemicals after the CMP process. In such conventional processes, a low-k dielectric material is often exposed to water in both the polishing step and the post-CMP cleaning, which as explained above, is detrimental to the low-k dielectric material.

Accordingly, what is needed in the art is a method of semiconductor manufacturing to protect low-k dielectric material from exposure to water during a CMP and post-CMP cleaning process, thereby: maintaining the dielectric constant of the low-k dielectric material; reducing the occurrence of subsequent cracking of the low-k dielectric material; protecting the low-k dielectric material from scratches and other mechanically induced damages during the CMP process; and, alleviating the difficulty of cleaning and drying the porous low-k dielectric material.

### SUMMARY

To address the above-discussed deficiencies of the prior art, in one embodiment, there is provided a method of manufacturing a semiconductor device. In this particular embodiment, the method comprises depositing a barrier layer over a low-k dielectric layer located over a semiconductor substrate over which a metal layer is deposited. A chemical mechanical polish process is used to remove a portion of the metal layer and the barrier layer and a dry etch is used to remove a remaining portion of the barrier layer.

In another embodiment, there is provided another method of manufacturing a semiconductor device. In this embodiment, the method comprises placing a low-k dielectric layer over a semiconductor substrate and depositing a hard mask layer over the low-k dielectric layer. A trench is formed in the low-k dielectric layer, and a metal barrier layer is deposited over the low-k dielectric layer and within the trench. A metal layer is deposited over the barrier layer and within the trench. A chemical mechanical polishing process is used to remove a portion of the metal layer and at least a portion of the barrier layer or the hard mask layer. A dry etch is used to remove another portion of the metal layer and remove a remaining portion of the barrier layer or the hard mask layer adjacent to the trench.

In yet another embodiment there is provided a semiconductor device. In this embodiment, the semiconductor device comprises a low-k dielectric layer located over a semiconductor substrate and a hard mask layer located over the low-k dielectric layer. A trench is located in the low-k dielectric layer with a metal barrier layer and a metal layer located therein. A portion of the metal layer and at least a portion of the metal barrier layer or the hard mask layer are removed using a wet chemical mechanical polishing process. Another portion of the metal layer and a remaining portion of the metal barrier layer or the hard mask layer adjacent to the trench are removed using a dry etch.

### BRIEF DESCRIPTION OF THE DRAWINGS

For a better understanding, reference is now made to the following descriptions taken in conjunction with the accompanying drawings, in which:

FIG. 1 illustrates an embodiment of a semiconductor device prior to the formation of an interconnect structure in accordance with the invention;

FIGS. 2A-2H illustrate an embodiment of a fabrication process in accordance with the invention; and

FIG. 3 illustrates a finished semiconductor device configured as an integrated circuit (IC) with at least two interconnect layers in accordance with the invention.

### DETAILED DESCRIPTION

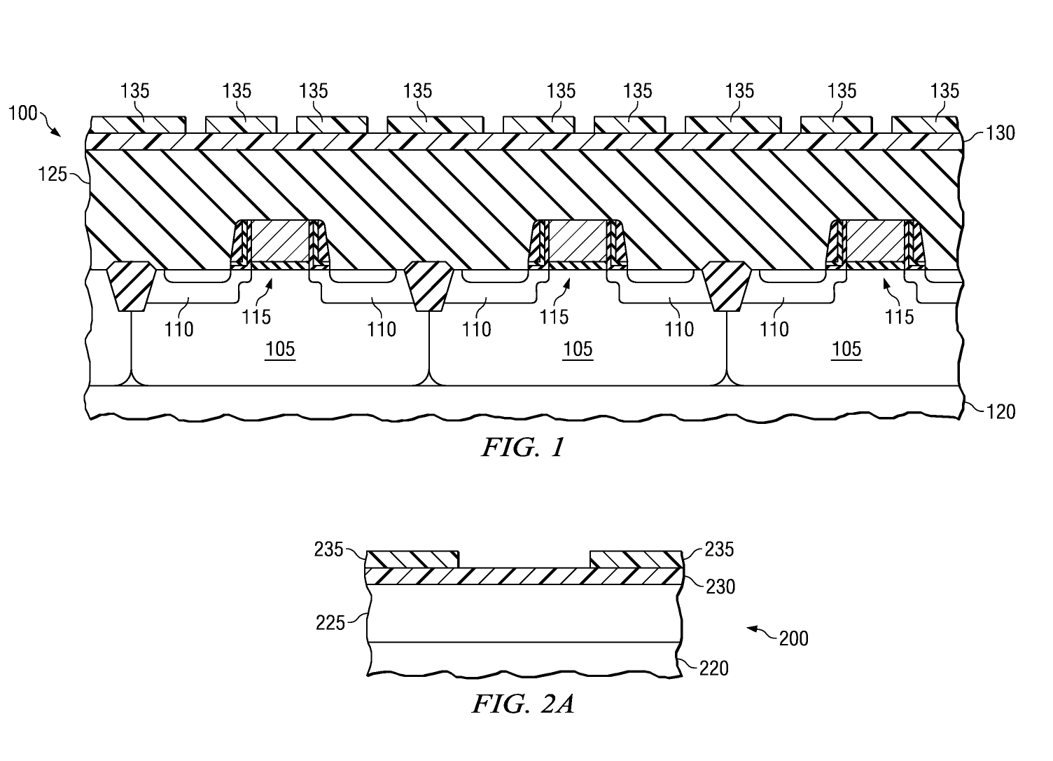

FIG. 1 illustrates a semiconductor device 100 that contains wells 105, source drain regions 110, and gate structures 115, which may include a gate electrode, gate oxide, and sidewall spacers. The wells 105, sources and drains 110, and gate structures 115 may be formed over a semiconductor substrate 120 with conventional materials and by conventional processes. The semiconductor device 100 contains standard electronic components, such as transistors, formed from the wells 105, sources and drains 110, and gate structures 115. A dielectric layer 125 is deposited over the standard electronic components using a conventional process and materials.

In one embodiment, the dielectric layer 125 may be a low-k dielectric material, such as organo silicate glass (OSG), and can be deposited by conventional process, e.g., a spin-on approach or chemical vapor deposition (CVD). As noted above, one reason a low-k dielectric material is used is to reduce parasitic capacitances between differing layers of dielectric materials, which allow for faster switching speeds and lower heat dissipation. A low-k dielectric material is a material that has a dielectric constant lower than that of silicon dioxide (which has a dielectric constant k≈3.9). Most low-k dielectric materials have a dielectric constant of less than 3.0.

A hard mask layer 130 can then be deposited over the low-k dielectric material 125. The hard mask layer 130 may be deposited with a conventional method, such as CVD, and typically consists of silicon nitride or silicon oxide material. A layer of polymeric photoresist 135 is deposited over the hard mask layer 130. Conventional processes may be used to deposit and pattern the photoresist layer 135 for subsequent trench etching.

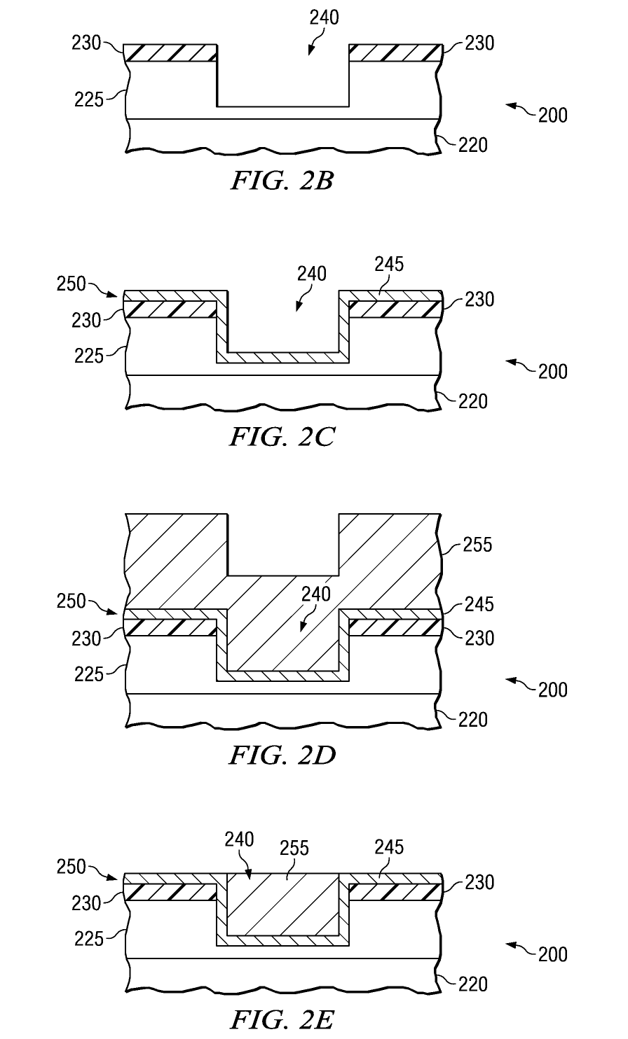

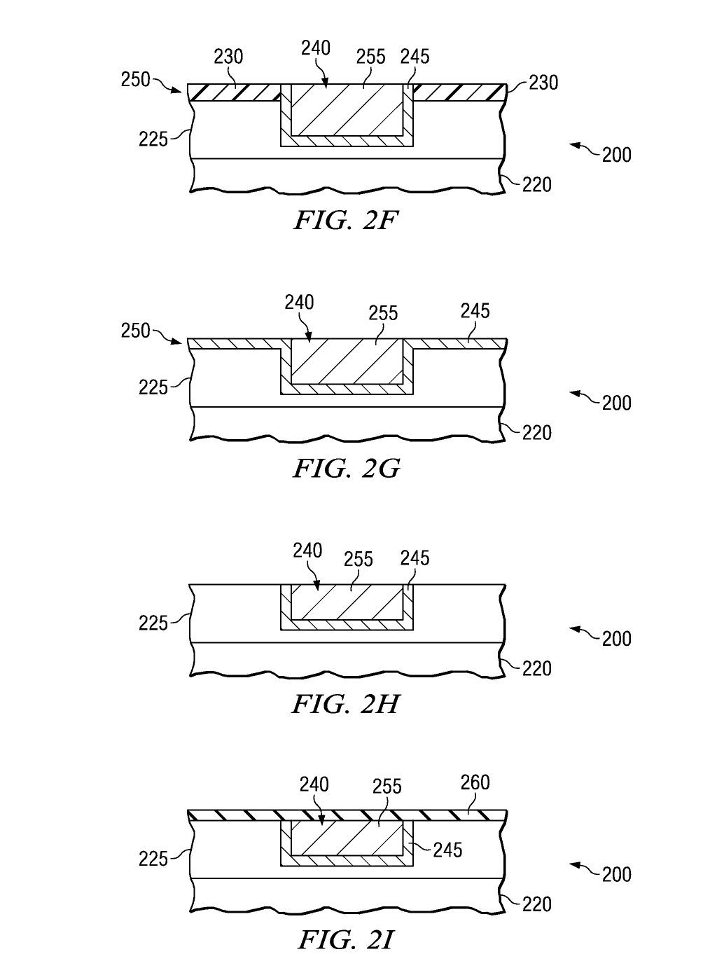

FIG. 2A illustrates a semiconductor device 200 with patterned openings in photoresist layer 235 and prior to etch. Also illustrated in FIG. 2A is an enlarged view of the semiconductor substrate 220, low-k dielectric material 225, and hard mask layer 230 of FIG. 1. FIG. 2B illustrates the semiconductor device 200 subsequent to an etch that forms trench 240 in the low-k dielectric material 225 and hard mask layer 230. The trench 240 may be etched with a conventional dry etch, such as a plasma etch.

Subsequent to formation of the trench 240, a barrier metal layer 245 is blanket deposited over the semiconductor device 200 as illustrated in FIG. 2C. The barrier metal layer 245 can be deposited with a conventional process. The barrier metal layer 245 may comprise tantalum, titanium, tantalum nitride, titanium nitride or combinations thereof. The metal layer 245 isolates the low-k dielectric material 225 from the effects of metal diffusion.

In one embodiment, the hard mask layer 230 and metal barrier layer 245 in combination form a barrier layer 250 to protect the porous low-k dielectric material layer 225 from a subsequent CMP process step. In another embodiment, the metal barrier layer 245 forms the barrier layer 250 protecting the porous low-k dielectric layer 225. In both embodiments, the metal barrier layer 245 may also serve as a diffusion barrier for a subsequent metal deposition in addition to protecting the porous low-l dielectric layer 225.

FIG. 2D illustrates the semiconductor device 200 subsequent to a blanket deposition of a metal interconnect layer 255. In one embodiment, the metal interconnect layer 255 is a low resistivity metal, such as copper. The blanket deposition, which may be a conventional process, fills the trench 240 with copper as well as deposits copper over the barrier layer 250 consisting of, in one embodiment, the hard mask layer 230 and metal barrier layer 245, or in another embodiment the metal barrier layer 245.

As described above, CMP is conducted to planarize the topography of semiconductor device 200 for subsequent layers of interconnect structures, in effect, planarizing the top surface of the semiconductor device 200. FIGS. 2E and 2F illustrate different embodiments where the barrier layer 250 is made up of both the hard mask layer 230 and barrier metal layer 245. FIG. 2E illustrates one embodiment where both the hard mask layer 230 and metal barrier layer 245 adjacent the trench 240 remain after the CMP process. FIG. 2F illustrates another embodiment where the barrier metal layer 245 outside the trench 240 is removed and the hard mask layer 230 remains after the CMP process. In both embodiments, the barrier layer 250 protects the low-k dielectric 225 from exposure to the water-based CMP process. Hence, the low-k dielectric 225 is not susceptible to the above-mentioned problems associated with a porous low-k dielectric material.

FIG. 2G illustrates an embodiment where the barrier layer 250 is the metal barrier layer 245. As illustrated in FIG. 2G, the metal barrier layer 245 adjacent the trench 240 remains after the CMP process, again protecting the porous low-k dielectric material 225 from the effects of the water-based CMP process.

Since the porous low-k dielectric material 225 is protected with the barrier layer 250, there is no need to maintain a short duration time between the CMP process and a next process step. Nor is there a need to keep the semiconductor device 200 in a dry environment, such as a nitrogen box. Also, there is no need to bake the semiconductor device 200.

Subsequent to the CMP process step, an etch stop layer 260, typically a silicon nitride or silicon carbide layer, is blanket deposited on the semiconductor device 200. A conventional process may be used to form the etch stop layer 260. Since the semiconductor device still has the barrier layer 250 over the low-k dielectric material 225, this layer, in one embodiment, is removed prior to the deposition of the etch stop layer 260. The semiconductor device 200 is placed in a conventional deposition machine. In a first chamber of the deposition machine, a non-selective sputter etch removes the barrier layer 250. The sputter etch is non-selective in that it is applied to the entire semiconductor device 200 rather than to a specific area of the semiconductor device 200. The sputter etch typically uses 1000 Watts of power, 5 micro Torr of pressure, and an AC bias of 500 Watts. FIG. 2H illustrates the semiconductor device 200 after the non-selective sputter etch in the first chamber of the deposition machine. Alternatively, the non-selective sputter etch to remove the barrier layer could be replaced with a conventional dry plasma etch process.

Subsequent to the non-selective sputter etch, the semiconductor device 200 is moved to a second chamber of the deposition machine without breaking the vacuum seal of the deposition machine. The silicon nitride or silicon carbide etch stop layer 260 is then deposited on the semiconductor device 200 in the second chamber of the deposition machine. The etch stop layer 260 is deposited over the copper metal layer 255 in the trench 240 and the low-k dielectric material 225. FIG. 2I illustrates the semiconductor device 200 after the etch stop layer 260 has been deposited in the second chamber of the deposition machine.

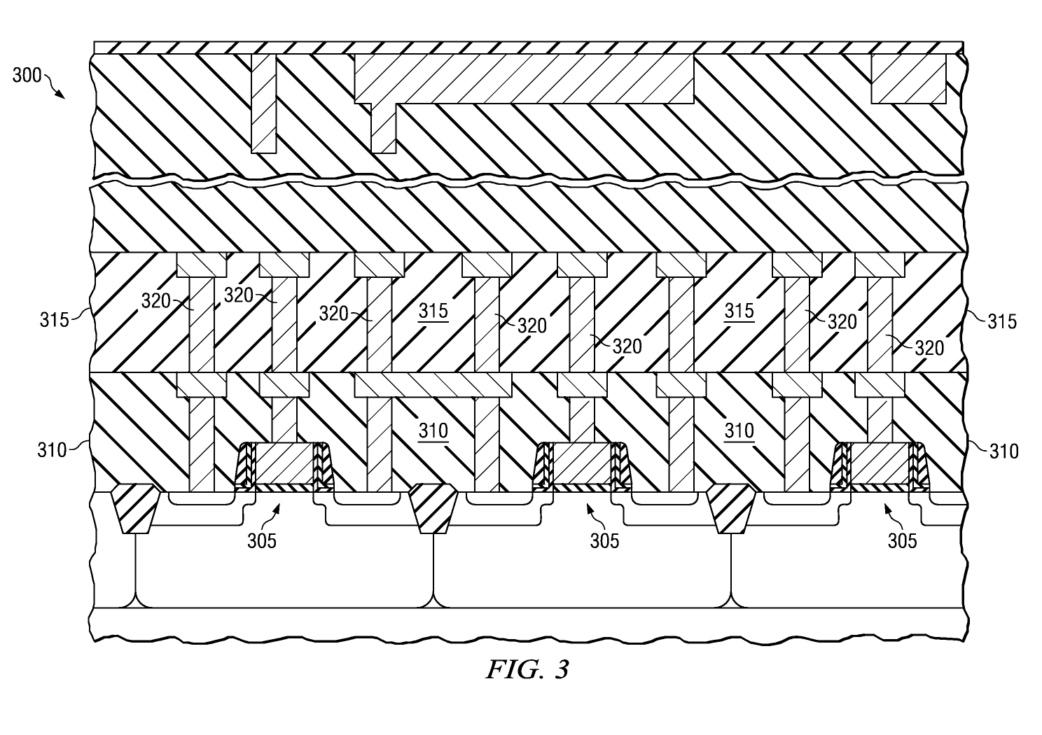

FIG. 3 illustrates the semiconductor device of the above-described embodiments as incorporated into an IC 300. In the illustrated embodiment, the IC 300 comprises transistors 305, which may include the components discussed above regarding FIG. 1. Low-k dielectric layers 310 and 315 are located over the transistors 305. Interconnects 320 that may be formed in the same manner as described above for semiconductor device 200 are located over and within the low-k dielectric layers 310 and 315. In the illustrated embodiment, the interconnects 320 are conventional dual damascene interconnects, however, in other embodiments, the interconnects 320 may be conventional single damascene interconnects or of some other conventional design.

Those skilled in the art will appreciate that other and further additions, deletions, substitutions, and modifications may be made to the described embodiments without departing from the scope of the invention.

What is claimed is:

1. A method of manufacturing a semiconductor device, comprising:
depositing a barrier layer over a low-k dielectric layer located over a semiconductor substrate;
depositing a metal layer over said barrier layer;
using a chemical mechanical process to remove a portion of said metal layer and said barrier layer; and
using a dry etch to remove a remaining portion of said barrier layer.

2. The method of claim 1 wherein said barrier layer comprises a tantalum/tantalum nitride barrier layer or a hard mask layer, or a combination thereof.

3. The method of claim 1 further comprising rinsing and cleaning said metal layer and said barrier layer subsequent to said using a chemical mechanical process and prior to said dry etch.

4. The method of claim 1 wherein said dry etch is a sputter etch.

5. The method of claim 4 wherein said sputter etch includes using a power of 1000 Watts, 5 micro Torr of pressure, and an AC bias of 500 Watts.

6. The method of claim 5 wherein said sputter etch is non-selective.

7. The method of claim 5 further comprising depositing an etch stop layer of silicon carbide or silicon nitride over said metal layer and said low-k dielectric layer subsequent to using said dry etch and without breaking a vacuum seal subsequent to said sputter etch.

8. The method of claim 1 wherein said dry etch is a plasma etch.

9. A method of manufacturing a semiconductor device, comprising:
placing a low-k dielectric layer over a semiconductor substrate;
depositing a hard mask layer over said low-k dielectric layer;
forming a trench in said low-k dielectric layer;
depositing a metal barrier layer over said low-k dielectric layer and within said trench;
depositing a metal layer over said barrier layer and within said trench;
using a chemical mechanical process to remove a portion of said metal layer and at least a portion of said barrier layer or said hard mask layer; and
using a dry etch to remove another portion of said metal layer, and remove a remaining portion of said barrier layer or said hard mask layer adjacent to said trench.

10. The method of claim 9 wherein said barrier layer comprises a tantalum/tantalum nitride barrier and said hard mask layer comprises silicon nitride.

11. The method of claim 9 further comprising rinsing and cleaning said metal layer and said barrier layer subsequent to said using a chemical mechanical process and prior to said dry etch.

12. The method of claim 9 wherein said dry etch is a sputter etch.

13. The method of claim 12, wherein the sputter etch includes using a power of 1000 Watts, 5 micro Torr of pressure, and an AC bias of 500 Watts.

14. The method of claim 9 wherein said dry etch is conducted in a chamber of a deposition tool.

15. The method of claim 13 further comprising depositing an etch stop layer of silicon carbide or silicon nitride over said metal layer and said low-k dielectric layer subsequent to using said dry etch without breaking a vacuum seal in said deposition tool.

16. The method of claim 9 wherein said dry etch is a plasma etch.

17. The method of claim 9 wherein said semiconductor device is an integrated circuit and said method further includes:
forming transistors having gate electrodes, source/drains, and wells associated therewith prior to placing said low-k dielectric layer over said semiconductor substrate and wherein said method further includes placing a plurality of said low-k dielectric layers over said transistors and depositing said metal layer over said metal barrier layer within said trench includes forming a plurality of interconnect structures within said plurality of said low-k dielectric layers.

18. The method of claim 17 wherein said interconnects are damascene or dual damascene interconnect structures.

19. A semiconductor device, comprising:
a low-k dielectric layer located over a semiconductor substrate;
a hard mask layer located over said low-k dielectric layer; and
a trench located in said low-k dielectric layer and having a metal barrier layer and a metal layer located therein, wherein a portion of said metal layer and at least a portion of said metal barrier layer or said hard mask layer having been removed using a wet chemical mechanical process and wherein another portion of said metal layer and a remaining portion of said metal barrier layer or said hard mask layer adjacent to said trench having been removed using a dry etch.
